(19) United States
(12) Patent Application Publication
(10) Pub. No.: US 2025/0112599 A1
(43) Pub. Date: Apr. 3, 2025

(54) NETWORK-ASSISTED SIGNALING FOR UPLINK DIGITAL PRE-DISTORTION (DPD)

(71) Applicant: Nokia Technologies Oy, Espoo (FI)

(72) Inventors: Jun TAN, Naperville, IL (US); Athul PRASAD, Naperville, IL (US); Amitabha CHOSH, Naperville, IL (US); Gilsoo LEE, Naperville, IL (US); Jie CHEN, Naperville, IL (US)

(21) Appl. No.: 18/560,865

(22) PCT Filed: Jun. 15, 2022
(86) PCT No.: PCT/EP2022/066252

§ 371 Date: Nov. 14, 2023

Related U.S. Application Data
(60) Provisional application No. 63/214,894, filed on Jun. 25, 2021.

(51) Int. Cl. H03F 1/32; H04B 1/04

(52) U.S. Cl. CPC H03F 1/3247; H04B 1/0475; H03F 2200/451; H04B 2001/0425

(57) ABSTRACT

Systems, methods, apparatuses, and computer program products for network-assisted signaling for uplink digital pre-distortion (DPD). A gNB may use an uplink reference signal (RS) to measure a user equipment's (UE's) power amplifier (PA) nonlinearity, where the UE may transmit its UE-specific RS with maximum transmit (Tx) power at a PA measurement window in the uplink. The gNB may train an artificial intelligence-based model to approximate the pre-distortion function (with PA parameters). The gNB may signal DPD-related information, and the UE may determine (and adjust) its DPD function based on the gNB signalling.

### FIELD

Some example embodiments may generally relate to mobile or wireless telecommunication systems, such as Long Term Evolution (LTE) or fifth generation (5G) radio access technology or new radio (NR) access technology, or other communications systems. For example, certain embodiments may relate to systems and/or methods for network-assisted signaling for uplink digital pre-distortion (DPD).

### BACKGROUND

Examples of mobile or wireless telecommunication systems may include the Universal Mobile Telecommunications System (UMTS) Terrestrial Radio Access Network (UTRAN), Long Term Evolution (LTE) Evolved UTRAN (E-UTRAN), LTE-Advanced (LTE-A), MulteFire, LTE-A Pro, and/or fifth generation (5G) radio access technology or new radio (NR) access technology. 5G wireless systems refer to the next generation (NG) of radio systems and network architecture. 5G is mostly built on a new radio (NR), but a 5G (or NG) network can also build on E-UTRA radio. It is estimated that NR may provide bitrates on the order of 10-20 Gbit/s or higher, and may support at least enhanced mobile broadband (eMBB) and ultra-reliable low-latency-communication (URLLC) as well as massive machine type communication (mMTC). NR is expected to deliver extreme broadband and ultra-robust, low latency connectivity and massive networking to support the Internet of Things (IoT). With IoT and machine-to-machine (M2M) communication becoming more widespread, there will be a growing need for networks that meet the needs of lower power, low data rate, and long battery life. It is noted that, in 5G, the nodes that can provide radio access functionality to a user equipment (i.e., similar to Node B in UTRAN or eNB in LTE) may be named gNB when built on NR radio and may be named NG-eNB when built on E-UTRA radio.

### SUMMARY

According to a first embodiment, an apparatus may include at least one processor and at least one memory including computer program code. The at least one memory and the computer program code may be configured to, with the at least one processor, cause the apparatus at least to receive an uplink reference signal for power amplifier measurement. The at least one memory and the computer program code may be configured to, with the at least one processor, cause the apparatus at least to measure a power amplifier nonlinearity of a user equipment based on the uplink reference signal. The at least one memory and the computer program code may be configured to, with the at least one processor, cause the apparatus at least to train an artificial intelligence-based model to approximate one or more power amplifier parameters based on an estimation of the power amplifier nonlinearity. The at least one memory and the computer program code may be configured to, with the at least one processor, cause the apparatus at least to use the trained artificial intelligence-based model to approximate the one or more power amplifier parameters. The at least one memory and the computer program code may be configured to, with the at least one processor, cause the apparatus at least to transmit, to a user equipment, signaling comprising the one or more power amplifier parameters.

In a variant, the at least one memory and the computer program code may be configured to, with the at least one processor, cause the apparatus, when measuring the power amplifier nonlinearity, at least to determine a power amplifier power profile difference between the received uplink reference signal and an output power profile associated with a known reference signal. In a variant, the at least one memory and the computer program code may be configured to, with the at least one processor, cause the apparatus, when training the artificial intelligence-based model, at least to train the artificial intelligence-based model using the power profile difference and a training criterion comprising minimization of the power difference. In a variant, the known reference signal may be generated based on an analytical power amplifier model. In a variant, the one or more power amplifier parameters may include an alpha parameter or a beta parameter associated with a general analytical power amplifier model.

In a variant, the at least one memory and the computer program code may be configured to, with the at least one processor, cause the apparatus at least to transmit a configuration related to the uplink reference signal for power amplifier measurement. In a variant, the at least one memory and the computer program code may be configured to, with the at least one processor, cause the apparatus at least to receive another uplink reference signal. In a variant, the uplink reference signal may be transmitted with a determined digital pre-distortion function adjusted based on the one or more power amplifier parameters. In a variant, the artificial intelligence-based model may include a neural network-based model. In a variant, the transmitted signaling may further include one or more digital pre-distortion function parameters.

According to a second embodiment, an apparatus may include at least one processor and at least one memory including computer program code. The at least one memory and the computer program code may be configured to, with the at least one processor, cause the apparatus at least to transmit an uplink reference signal for power amplifier measurement. The at least one memory and the computer program code may be configured to, with the at least one processor, cause the apparatus at least to receive signaling comprising one or more power amplifier parameters. The at least one memory and the computer program code may be configured to, with the at least one processor, cause the apparatus at least to determine a digital pre-distortion function of the apparatus based on the one or more power amplifier parameters. The at least one memory and the computer program code may be configured to, with the at least one processor, cause the apparatus at least to transmit an uplink signal with the digital pre-distortion function adjusted based on the one or more power amplifier parameters.

In a variant, the at least one memory and the computer program code may be configured to, with the at least one processor, cause the apparatus, when determining the digital pre-distortion function, at least to use an analytical model to determine the digital pre-distortion function based on the one or more power amplifier parameters. In a variant, the at least one memory and the computer program code may be configured to, with the at least one processor, further cause the apparatus, when determining the digital pre-distortion function, at least to use a trained artificial intelligence-based model to determine the digital pre-distribution function. In a variant, the at least one memory and the computer program code may be configured to, with the at least one processor, further cause the apparatus at least to train an artificial intelligence-based model to fit a power amplifier model controlled by the one or more power amplifier parameters.

In a variant, the training may form the trained artificial intelligence-based model. In a variant, the training may be based on an uplink reference signal transmitted to a network node and a non-linear power profile difference between the uplink reference signal and a known reference signal associated with the power amplifier model. In a variant, the at least one memory and the computer program code may be configured to, with the at least one processor, further cause the apparatus at least to train an artificial intelligence-based model to fit a power amplifier model controlled by the one or more power amplifier parameters. In a variant, the training may form the trained artificial intelligence-based model. In a variant, the training may be based on an uplink reference signal transmitted to a network node, a non-linear power profile difference between the uplink reference signal and a known reference signal associated with the power amplifier model, and the one or more power amplifier parameters. In a variant, the at least one memory and the computer program code may be configured to, with the at least one processor, further cause the apparatus, when transmitting the uplink signal, at least to transmit the uplink signal with the digital pre-distortion function determined using the trained artificial intelligence model. In a variant, the one or more power amplifier parameters may include an alpha parameter or a beta parameter associated with a general analytical power amplifier model. In a variant, the received signaling may further include one or more digital pre-distortion function parameters.

According to a third embodiment, a method may include receiving an uplink reference signal for power amplifier measurement. The method may include measuring a power amplifier nonlinearity of a user equipment based on the uplink reference signal. The method may include training an artificial intelligence-based model to approximate one or more power amplifier parameters based on an estimation of the power amplifier nonlinearity. The method may include using the trained artificial intelligence-based model to approximate the one or more power amplifier parameters. The method may include transmitting, to a user equipment, signaling comprising the one or more power amplifier parameters.

In a variant, the measuring the power amplifier nonlinearity may further include determining a power amplifier power profile difference between the received uplink reference signal and an output power profile associated with a known reference signal. In a variant, the training the artificial intelligence-based model may further include training the artificial intelligence-based model using the power profile difference and a training criterion comprising minimization of the power difference. In a variant, the known reference signal may be generated based on an analytical power amplifier model.

In a variant, the one or more power amplifier parameters may include an alpha parameter or a beta parameter associated with a general analytical power amplifier model. In a variant, the method may further include transmitting a configuration related to the uplink reference signal for power amplifier measurement. In a variant, the method may further include receiving another uplink reference signal. In a variant, the uplink reference signal may be transmitted with a determined digital pre-distortion function adjusted based on the one or more power amplifier parameters. In a variant, the artificial intelligence-based model may include a neural network-based model. In a variant, the transmitted signaling may further include one or more digital pre-distortion function parameters.

According to a fourth embodiment, a method may include transmitting, by a user equipment, an uplink reference signal for power amplifier measurement. The method may include receiving signaling comprising one or more power amplifier parameters. The method may include determining a digital pre-distortion function of the user equipment based on the one or more power amplifier parameters. The method may include transmitting an uplink signal with the digital pre-distortion function adjusted based on the one or more power amplifier parameters.

In a variant, the determining the digital pre-distortion function may further include using an analytical model to determine the digital pre-distortion function based on the one or more power amplifier parameters. In a variant, the determining the digital pre-distortion function may further include using a trained artificial intelligence-based model to determine the digital pre-distribution function. In a variant, the method may further include training an artificial intelligence-based model to fit a power amplifier model controlled by the one or more power amplifier parameters. In a variant, the training may form the trained artificial intelligence-based model. In a variant, the training may be based on an uplink reference signal transmitted to a network node and a non-linear power profile difference between the uplink reference signal and a known reference signal associated with the power amplifier model. In a variant, the method may further include training an artificial intelligence-based model to fit a power amplifier model controlled by the one or more power amplifier parameters. In a variant, the training may form the trained artificial intelligence-based model. In a variant, the training may be based on an uplink reference signal transmitted to a network node, a non-linear power profile difference between the uplink reference signal and a known reference signal associated with the power amplifier model, and the one or more power amplifier parameters. In a variant, the transmitting the uplink signal may further include transmitting the uplink signal with the digital pre-distortion function determined using the trained artificial intelligence model. In a variant, the one or more power amplifier parameters may include an alpha parameter or a beta parameter associated with a general analytical power amplifier model. In a variant, the received signaling may further include one or more digital pre-distortion function parameters.

A fifth embodiment may be directed to an apparatus that may include circuitry configured to cause the apparatus to perform the method according to the third embodiment or fourth embodiment, or any of the variants discussed above.

A sixth embodiment may be directed to an apparatus that may include means for performing the method according to the third embodiment or the fourth embodiment, or any of the variants discussed above. Examples of the means may include one or more processors, memory, and/or computer program codes for causing the performance of the operation.

A seventh embodiment may be directed to a computer readable medium comprising program instructions stored thereon for causing an apparatus to perform at least the method according to the third embodiment or the fourth embodiment, or any of the variants discussed above.

An eighth embodiment may be directed to a computer program product encoding instructions for causing an apparatus to perform at least the method according to the third embodiment or the fourth embodiment, or any of the variants discussed above.

### BRIEF DESCRIPTION OF THE DRAWINGS

For proper understanding of example embodiments, reference should be made to the accompanying drawings, wherein:

FIG. 1 illustrates an example of network-assisted signaling for uplink DPD, according to some embodiments;

FIG. 2 illustrates an example of power amplifier parameter estimation using an artificial intelligence-based model, according to some embodiments;

FIG. 3 illustrates an example plot of Salah's power amplifier model, according to some embodiments;

FIG. 4 illustrates an example of artificial intelligence-based DPD, according to some embodiments;

FIG. 5 illustrates an example of artificial intelligence-based DPD with power amplifier parameters as inputs, according to some embodiments;

FIG. 6 illustrates an example flow diagram of a method, according to some embodiments;

FIG. 7 illustrates an example flow diagram of a method, according to some embodiments;

FIG. 8a illustrates an example block diagram of an apparatus, according to an embodiment; and

FIG. 8b illustrates an example block diagram of an apparatus, according to another embodiment.

### DETAILED DESCRIPTION

It will be readily understood that the components of certain example embodiments, as generally described and illustrated in the figures herein, may be arranged and designed in a wide variety of different configurations. Thus, the following detailed description of some example embodiments of systems, methods, apparatuses, and computer program products for network-assisted signaling for uplink DPD is not intended to limit the scope of certain embodiments but is representative of selected example embodiments.

The features, structures, or characteristics of example embodiments described throughout this specification may be combined in any suitable manner in one or more example embodiments. For example, the usage of the phrases “certain embodiments,” “some embodiments,” or other similar wording, throughout this specification refers to the fact that a particular feature, structure, or characteristic described in connection with an embodiment may be included in at least one embodiment. Thus, appearances of the phrases “in certain embodiments,” “in some embodiments,” “in other embodiments,” or other similar wording, throughout this specification do not necessarily all refer to the same group of embodiments, and the described features, structures, or characteristics may be combined in any suitable manner in one or more example embodiments. In addition, the phrase “set of” refers to a set that includes one or more of the referenced set members. As such, the phrases “set of,” “one or more of,” and “at least one of,” or equivalent phrases, may be used interchangeably. Further, “or” is intended to mean “and/or,” unless explicitly stated otherwise.

Additionally, if desired, the different functions or operations discussed below may be performed in a different order and/or concurrently with each other. Furthermore, if desired, one or more of the described functions or operations may be optional or may be combined. As such, the following description should be considered as merely illustrative of the principles and teachings of certain example embodiments, and not in limitation thereof.

In a wireless or wireline commination system, the linearity of a transmission power amplifier (PA) may be a limiting factor. The nonlinearity of the PA may generate unwanted distortion in transmitted signals, and the distortion may cause adjacent frequency leakage, may increase interference, and/or may degrade receive (Rx) performance. In these scenarios, transmit (Tx) power back-off may be applied, which may mitigate the nonlinearity problem but with lower Tx power efficiency.

A digital domain solution, such as a digital pre-distortion (DPD), may be applied before the PA in a circuit to reduce the impact of nonlinear distortion. An inverse function, or pre-distortion function, may be applied before the PA, so that the combination of the pre-distortion and the PA may resemble a linear mapping between input voltage Vᵢ and output voltage Vₒ. Instead of operating at the analog domain, the pre-distortion may be operating in the digital baseband, called digital pre-distortion, to simplify the transmitter design. If the PA is operating in compression at power output (Pₒᵤₜ), the Tx signal at the PA output may suffer nonlinearity when the instantaneous Tx power exceeds the linear region. With pre-distortion, the PA may generate its output at power output minus pre-distortion (P_{out-pd}), with raised linear outputs. The pre-distortion may provide the PA input power (Pᵢₙ) minus pre-distortion (P_{in-pd}) to yield the desired output power P_{out-pd}.

The pre-distortion may have the identification of the pre-distortion function so that the DPD can be applied to mitigate the PA efficiency issue. One problem may include the identification of the pre-distortion function, or DPD function, given a power amplifier. In wireless communication, at the base station, the estimation of DPD may involve various measurements of the power amplifier of the base station. At the UE, the identification of the UE's PA pre-distortion function may be complicated, because the UE may not computationally afford extensive measurement of the PA.

As mentioned above, one problem may be the identification of the pre-distortion function of the PA at the UE. In a wireless system, such as a 5G NR network, the linearity of the UE's PA may have a lower grade or quality than that of the PA at the base station. The usual approach to mitigate the nonlinear distortion may be to apply power back-off. Due to the high peak-to-average power ratio (PAPR) of orthogonal frequency division multiplexed (OFDM) signals used in NR uplink, the power back-off may be as high as 3 decibels (dBs), which may degrade uplink Tx power efficiency. A Tx power back-off may reduce uplink performance in coverage, data throughput, and latency.

It may be desirable to apply DPD technique used in the base station to the UE. However, direct application of DPD to the UE may be complicated and/or computationally intense, and the PA grade at the UE may be lower than the PA grade at the base station. A UE may not have the computing resources to provide a simultaneous Rx circuit to measure its PA characteristic online and, therefore, the direct identification of the DPD function may not be available for the UE. This may be a problem for the application of DPD techniques at the UE side.

Given that the network may have more computing power than the UE, a gNB may assist in DPD estimation for a UE in a NR network. However, with network assistance, there may still be issues. One issue may be related to the identification of the UE's DPD functions, given that there may be various types of UEs with different PA implementations. Another issue may be related to the signalling of the UE's DPD functions, from the gNB to the UE, where the signalling may capture the key factors of DPD functions for PAs in the network. Another issue may be related to the application of DPD at the UE, where the UE can convert the signalling into useful DPD functions for pre-distortion. As can be understood from the above, there may be a need for network-assisted signaling for uplink DPD.

Some embodiments described herein may provide for network-assisted signaling for uplink DPD. Certain embodiments described herein may perform estimation of a DPD function. In an embodiment, a gNB may use an uplink reference signal (RS) (e.g., a power measurement reference signal (PMRS)) to measure the UE's PA nonlinearity, where the UE may transmit its UE-specific PMRS with maximum Tx power at a PA measurement window in the uplink and the UE-specific PMRS may have a large peak-to-average-power ratio (PAPR) property (e.g., a large PAPR may mean that a power range is sufficiently large to enable measurement of the PA nonlinearity). In certain embodiments, the gNB may train an artificial intelligence-based model (e.g., a neural network) to approximate the pre-distortion function (e.g., a DPD function) with a PA parameter. Certain embodiments may signal DPD-related information. For example, the gNB may signal pre-distortion (e.g., DPD) function parameters, such as alpha and/or beta parameters, based on a specific PA model, to a UE with either physical downlink control channel (PDCCH) or medium access control control element (MAC CE) signalling. Certain embodiments may include DPD-related operations. For example, the UE may determine (or adjust) its DPD function based on the gNB signalling. In one example, the DPD function may be implemented in a pre-trained neural network.

In this way, by applying DPD implementation at the UE, certain embodiments may provide improved UE PA linearity and PA efficiency by reducing or eliminating the need for uplink power back-off. Given that the uplink Tx power may be the weakest link in a NR cellular deployment, application of the DPD at the UE may enhance uplink performance. By conducting PA DPD training at the gNB, which may have more processing capability than the UE, certain embodiments may reduce or eliminate the complexity of model training at the UE. Training at the gNB may also reduce costs because UE-implemented training may be too expensive to be practical for many use cases.

According to certain embodiments, 4 PA parameter values per UE may have to be used to signal by the gNB. The low payload of signalling may reduce the amount of signalling overhead relative to other techniques described above, which conserves network resources. As a result, the cost of the signalling may not be significant. The UE may have its choices to adjust its DPD function based on the gNB's signalling. For example, the UE can use a pre-trained DPD implementation, or the UE can use the PA parameter to load its pre-trained DPD model. No Rx measurement may be needed for the UE's DPD implementation. This may further provide flexibility for the UE's PA implementation so that the proposed approach may be applicable for various UE types.

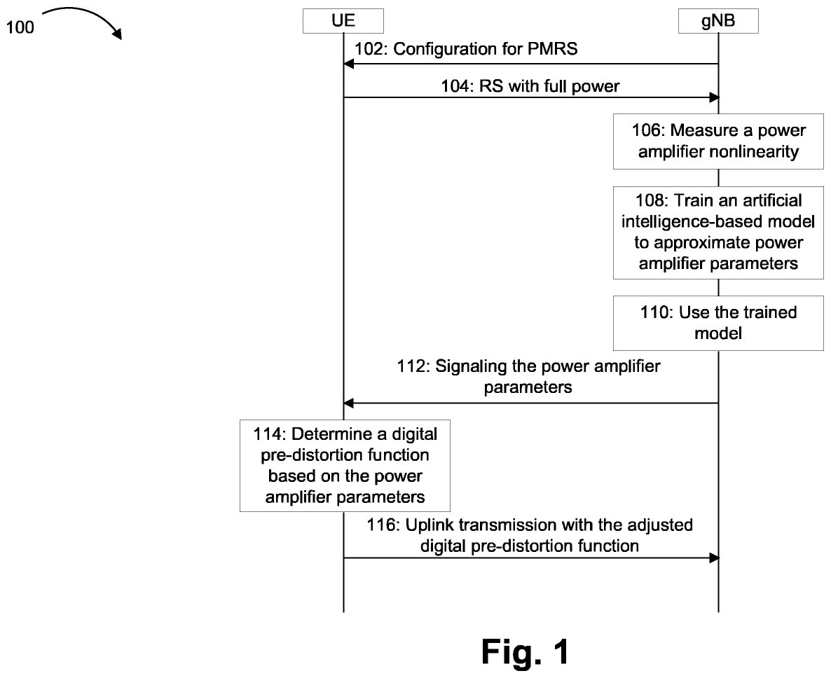

FIG. 1 illustrates an example 100 of network-assisted signaling for uplink DPD, according to some embodiments. For example, FIG. 1 illustrates UE DPD training and signaling procedures, according to certain embodiments. As illustrated in FIG. 1, the example 100 includes a UE and gNB.

As illustrated at 102, the gNB may transmit, and the UE may receive, a configuration for a PMRS. For example, in a configuration process, the gNB may configure a PMRS for a specific UE. The configuration may include an uplink resource allocation for the specific UE. The allocated uplink resource may be used to transmit the PMRS to measure the linearity of the UE's PA. The gNB may send the trigger information to enable the UE to transmit the RS for a PA measurement, based on uplink channel conditions and/or a scheduler request. For example, the gNB may trigger the PA measurement for a UE when the uplink channel is close to line-of-sight (LOS).

As illustrated at 104, the UE may transmit, and the gNB may receive, the RS transmission (e.g., PMRS), such as at full power (or another power level, in certain embodiments). For example, when the gNB sends its RS triggering information to a UE, the UE may transmit a PMRS with full power. This may enable the gNB to conduct a PA measurement for the specific UE. The PMRS transmission may be configured as semi-persistent, meaning that the PMRS can be a periodic transmission after triggering, as described elsewhere herein.

As illustrated at 106, the gNB may measure a power amplifier nonlinearity. For example, when the UE is transmitting the PMRS, the gNB may use the uplink signal to measure the UE's PA linearity and to estimate the related DPD function. Although various estimation methods for PA nonlinearity can be applied, certain embodiments may use artificial intelligence-based model training with a PA mathematical model.

This may enable the gNB to determine the nonlinearity of the UE's PA. In the example 100, the gNB may train an artificial intelligence-based model to approximate power amplifier parameters, at 108, and may, at 110, use the trained model to approximate the power amplifier parameters. With a general mathematical model of the UE's amplifier, the learned PA nonlinearity property may be provided back to the UE for its DPD operation, as described below.

As illustrated at 112, the gNB may signal the power amplifier parameters to the UE. For example, once the gNB completes the training of the PA model for a specific UE, the PA model may be represented as parameters of a mathematical PA model. The determined PA parameters may be signalled back to the UE, and the signalling of the PA parameters may be transmitted via either PDCCH or MAC CE to the specific UE.

As illustrated at 114, the UE may determine a digital pre-distortion function based on the power amplifier parameters. For example, when the UE receives the signalling of its PA parameters, the UE may use the PA parameters for its pre-distortion operation. Depending on the UE's PA implementation and UE capability, the UE may use the signalled parameters with different approaches. For example, a neural-network based approach or another digital pre-distortion function can be applied with the input of the signalled PA parameters. As illustrated at 116, the UE may transmit, and the gNB may receive, an uplink transmission with the adjusted digital pre-distortion function. For example, the digital pre-distortion function may be adjusted based on the one or more power amplifier parameters.

As described above, FIG. 1 is provided as an example. Other examples are possible, according to some embodiments.

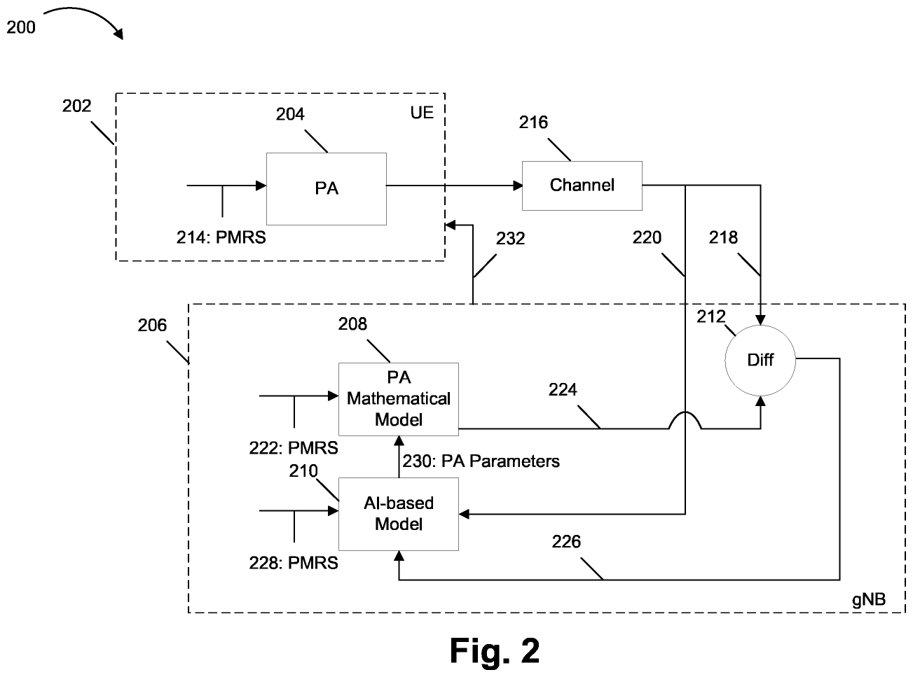

FIG. 2 illustrates an example 200 of power amplifier parameter estimation using an artificial intelligence-based model, according to some embodiments. For example, the example 200 may illustrate operations related to a power amplifier measurement with an artificial intelligence-based model (e.g., a neural network). As illustrated in FIG. 2, the example 200 includes a UE 202 that includes a PA 204. In addition, the example 200 includes a gNB 206 that includes a PA mathematical model 208, an AI-based model 210, and a differential element 212.

As illustrated at 214, the UE 202 may provide, via the PA 204 and a channel 216 (e.g., an uplink channel), a PMRS. As illustrated at 218, the PMRS may be provided as an input to the differential element 212 and, as illustrated at 220, the PMRS may be provided as an input to the AI-based model 210. As illustrated at 222, the gNB 206 may provide another PMRS (e.g., with pre-determined parameters, such as Tx signal strength), which may be similar to the UE's PMRS of 214 to the PA mathematical model 208 to generate a known PMRS. As illustrated at 224, the known PMRS may be provided as an input to the differential element 212. The differential element 212 may determine a power profile difference between the PMRS received at 218 and the PMRS received at 224, such as a measurement of nonlinearity of the PMRS received at 218, and may output the difference to the AI-based model 210, as illustrated at 226. As illustrated at 228, the gNB 206 may input a pre-determined PMRS to the AI-based model 210. The AI-based model 210 may process the PMRS received at 228, the PMRS received at 220, and the power profile difference received at 226 to train the AI-based model 210 to approximate PA parameters, which are output to the PA mathematical model 208, as illustrated at 230. In some embodiments, the operations illustrated at 218, 220, 222, 224, 226, 228, and 230 may be repeated one or more times to use the PA mathematical model 208 and the AI-based model 210 to approximate the PA parameters. As described elsewhere herein, after using the PA mathematical model 208 and the AI-based model 210 to approximate the PA parameters, the gNB 206 may output the approximated PA parameters to the UE 202, as illustrated at 232.

In this way, in the example 200, PA parameters may be estimated with, e.g., an AI-based model, such as a neural network. The neural network may be trained to estimate power amplifier parameters (based on a PA mathematical model). Inputs to the neural network may include a known PMRS signal and a received signal from a UE. A power profile difference between the received signal and the output of the generated PA mathematical model may be used as the measure for the neural network training. The training criterion for the neural network may include the minimization of the power difference between the received PMRS signal and the generated PA output from the PA mathematical model. Here the propagation channel may be known, where the channel can be estimated with a channel estimation algorithm (e.g., minimum mean squared error (MMSE) estimator, least squared (LS) error estimator, and/or the like).

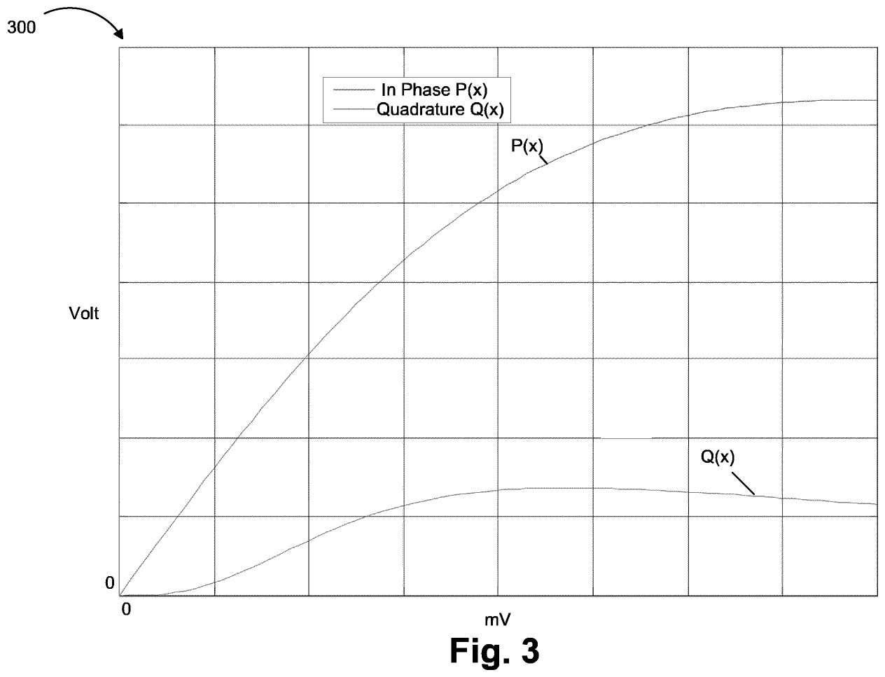

In one embodiment, the PA mathematical model may be based on an analytical PA model, such as Salah's PA model. Salah's PA model may be represented as:

$$P ( r ) = \frac{{α}_{p} r}{1 + {β}_{p} {r}^{2}} \qquad ( 1 )$$

$$Q ( r ) = \frac{{α}_{p} {r}^{3}}{{( 1 + {β}_{q} {r}^{2} )}^{2}} \qquad ( 2 )$$

where the variable r may represent the input voltage of the power amplifier, and P(r) and Q(r) may represent the in-phase and quadrature components of the PA's outputs, respectively. This model may have two parameters per dimension, with a total of 4 parameters (αₚ, βₚ, α_{q}, β_{q}) to identify the PA mathematical model. One example of an input and output plot of the PA mathematical model is illustrated in FIG. 3, described below.

As indicated above, FIG. 2 is provided as an example. Other examples are possible, according to some embodiments.

FIG. 3 illustrates an example plot 300 of Salah's power amplifier model, according to some embodiments. With this model, just 4 parameters may be used to identify the power amplifier. For example, the AI-based model 216 illustrated in FIG. 2 may provide the estimation of the 4 parameters to match the UE's PA model. The gNB may signal the PA parameters to the UE for DPD operation at the UE, as described elsewhere herein.

As described above, FIG. 3 is provided as an example. Other examples are possible, according to some embodiments.

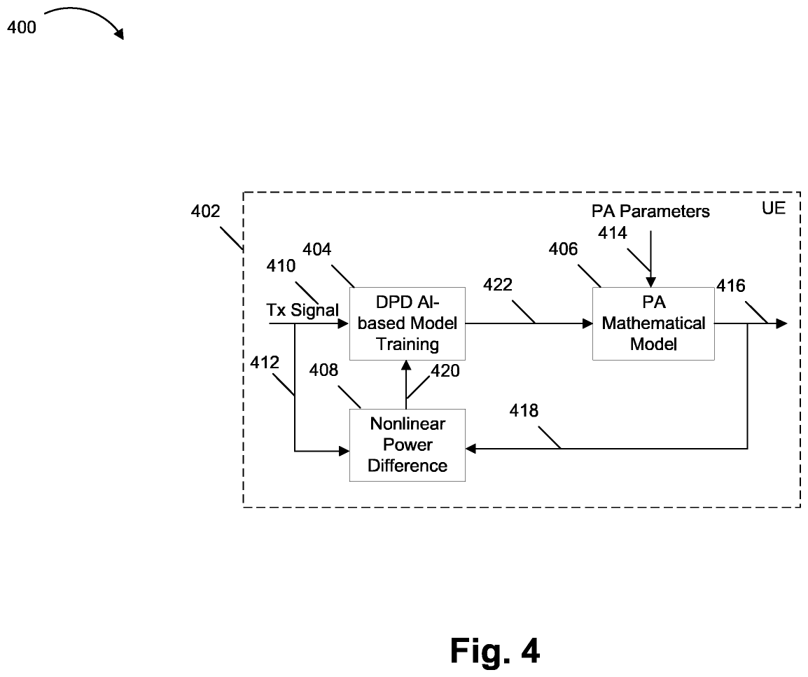

FIG. 4 illustrates an example 400 of artificial intelligence-based DPD, according to some embodiments. In particular, FIG. 4 illustrates certain embodiments related to PA parameter signaling and pre-distortion, such as neural network-based DPD. As illustrated in FIG. 4, the example 400 includes a UE 402 that includes a DPD AI-based model training element 404, a PA mathematical model 406, and a nonlinear power difference element 408.

As illustrated at 410, the UE 402 may input a transmit (Tx) signal to the DPD AI-based model training element 404 and, at 412, to the nonlinear power difference element 408. As illustrated at 414, the UE 402 may input PA parameters received from a gNB (e.g., from the gNB 206 at 232 of FIG. 2) to the PA mathematical model 406, and the PA mathematical model 406 may generate a known reference signal based on the PA parameters received at 414. As illustrated in FIG. 4, the PA mathematical model 406 may output the known reference signal at 416, which may be input to the nonlinear power difference element 408 at 418, and the nonlinear power difference element 408 may determine a power profile difference between the Tx signal input at 412 and the known reference signal input at 418. The determined nonlinear power profile difference element 408 may output, at 420, the determined power profile difference to the DPD AI-based model training element 404 for training to determine a DPD function. The DPD AI-based model training element 404 may then output, at 422, a DPD function to the PA mathematical model 406, and the operations illustrated at 416, 418, 420, and 422 may be repeated to improve the determination of the DPD function.

In this way, when the PA parameters are estimated at the gNB, the parameters can be signalled with, e.g., physical downlink control channel (PDCCH) or MAC CE to the UE. For example, there may be 4 parameters based on the PA model. If 6-bit quantization is applied for each parameter, a total of 24-bits may be sufficient to signal a PA model. Once the PA model is provided back to the UE, the UE may perform pre-distortion as part of the DPD process. There may be one or more approaches that can be applied to a known PA model for the DPD operation, according to some embodiments. As illustrated in, and described with respect to, FIG. 4, the UE may use offline training to utilize a neural network to perform the pre-distortion. During the offline training, the UE may use a neural network to train a DPD function to compensate for the nonlinearity of a PA model, which may be controlled by the PA parameters as inputs. Given one set of PA parameters, the offline training process may train a neural network to approximate the DPD function to fit the respective PA model. With multiple sets of PA parameters, multiple networks can be trained. The trained neural networks, together with the corresponding PA parameters, can be pre-stored. During the online operation, the UE can load a stored neural network based on the PA parameters from the gNB to perform the DPD operation. Because the training process may be performed offline, online training computing resources may be conserved.

As an alternative to certain embodiments illustrated in, and described with respect to, FIG. 4, the UE may use the analytical model to output the pre-distortion function based on various PA parameters. If the analytical model (PA mathematical model) is known to the UE (e.g., Salah's model), the UE may use the related inverse function to determine different pairs of PA parameters, such as alpha (α) and beta (β) parameters.

As described above, FIG. 4 is provided as an example. Other examples are possible, according to some embodiments.

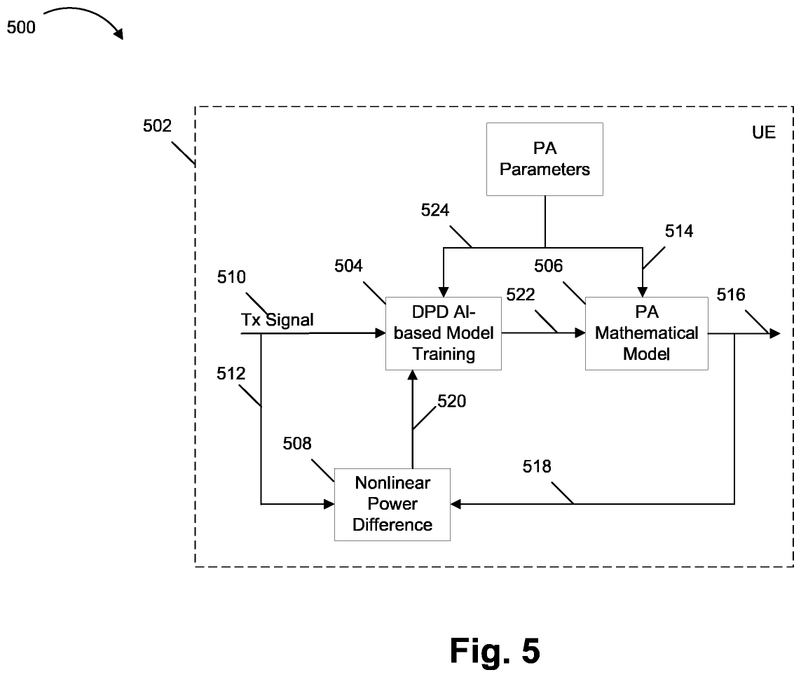

FIG. 5 illustrates an example 500 of artificial intelligence-based DPD with power amplifier parameters as inputs, according to some embodiments. In particular, FIG. 5 illustrates certain embodiments related to PA parameter signaling and pre-distortion, such as neural network-based DPD with PA parameters as inputs. As illustrated in FIG. 5, the example 500 includes a UE 502 that includes a DPD AI-based model training element 504, a PA mathematical model 506, and a nonlinear power difference element 508. The DPD AI-based model training element 504, the PA mathematical model 506, and the nonlinear power difference element 508 may be similar to the DPD AI-based model training element 404, the PA mathematical model 406, and the nonlinear power difference element 408, respectively, illustrated in, and described with respect to, FIG. 4. Furthermore, the operations 508, 510, 512, 514, 516, 518, 520, and 522 may be similar to operations 408, 410, 412, 414, 416, 418, 420, and 422, respectively, illustrated in, and described with respect to, FIG. 4. In addition, as illustrated in FIG. 5 at 524, instead of training one AI-based model to approximate one DPD function with a set of PA parameters, a larger AI-based model can be trained with PA parameters as input.

As described above, FIG. 5 is provided as an example. Other examples are possible, according to some embodiments.

The DPD training processes illustrated in, and described with respect to, FIGS. 4 and 5 may use a PA mathematical model for offline training. As such, no Rx measurement may have to be performed during the training process, which conserves network resources and computing resources and provides a low cost training benefit for UE implementation. The offline training may be based on the PA mathematical model. In some cases, the implemented PA model may not match the PA mathematical model, such as Salah's model. Although Salah's model may be an analytical power amplifier model (e.g., a general PA model), analytical power amplifier models according to certain embodiments may vary based on UE implementation. Therefore, certain embodiments may match the parameters of a particular PA nonlinearity property to the general mathematical model.

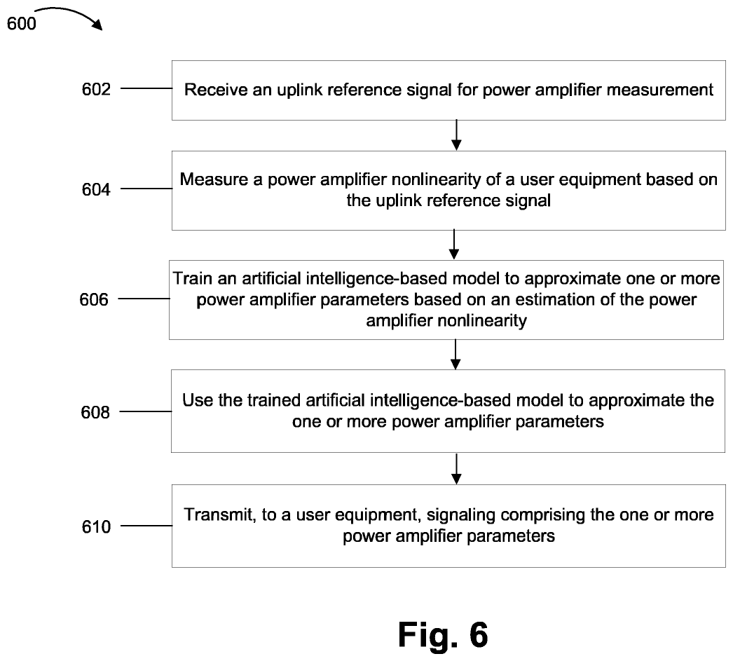

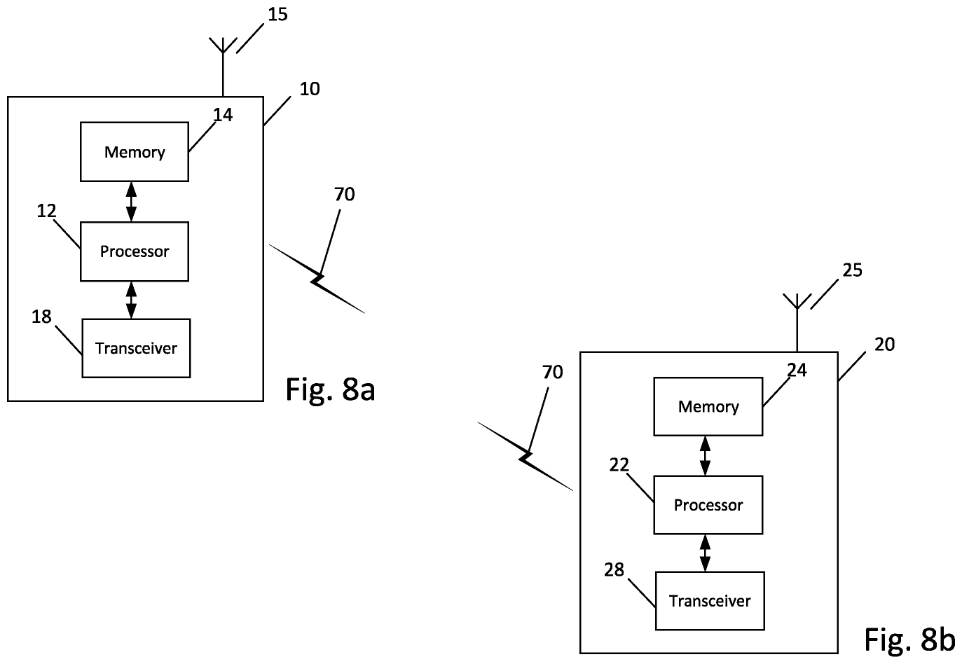

FIG. 6 illustrates an example flow diagram of a method 600, according to some embodiments. For example, FIG. 6 may illustrate example operations of a network node (e.g., apparatus 10 illustrated in, and described with respect to, FIG. 8a). For example, FIG. 6 may illustrate some operations of a gNB. Some of the operations illustrated in FIG. 6 may be similar to some operations shown in, and described with respect to, FIGS. 1-5.

In an embodiment, the method 600 may include, at 602, receiving an uplink reference signal for power amplifier measurement, e.g., in a manner similar to that at 104 of FIG. 1 and/or at 218 and 220 of FIG. 2. The method 600 may include, at 604, measuring a power amplifier nonlinearity of a user equipment based on the uplink reference signal, e.g., in a manner similar to that at 106 of FIG. 1 and/or that performed by the differential element 212 of FIG. 2. The method 600 may include, at 606, training an artificial intelligence-based model to approximate one or more power amplifier parameters based on an estimation of the power amplifier nonlinearity, e.g., in a manner similar to that at 108 of FIG. 1 and/or that performed by the AI-based model 210 of FIG. 2. The method 600 may include, at 608, using the trained artificial intelligence-based model to approximate the one or more power amplifier parameters, e.g., in a manner similar to that at 110 of FIG. 1 and/or that performed by the AI-based model 210 of FIG. 2. The method 600 may further include, at 610, transmitting, to a user equipment, signaling comprising the one or more power amplifier parameters, e.g., in a manner similar to that at 112 of FIG. 1 and/or that at 232 of FIG. 2.

The method illustrated in FIG. 6 may include one or more additional aspects described below or elsewhere herein. In some embodiments, the measuring at 604 may include determining a power amplifier power profile difference between the received uplink reference signal and an output power profile associated with a known reference signal (e.g., a difference between the signaling at 218 and the signaling at 224 determined by the differential element 212 of FIG. 2). In some embodiments, the training at 606 may include training the artificial intelligence-based model using the power profile difference (e.g., the power profile difference output from the differential element 212 at 226) and a training criterion may include minimization of the power difference. In some embodiments, the known reference signal may be generated based on an analytical power amplifier model (e.g., the PA mathematical model 208 of FIG. 2), such as Salah's power amplifier model.

In some embodiments, the one or more power amplifier parameters may include an alpha parameter or a beta parameter associated with a general analytical power amplifier model, such as Salah's power amplifier model. In some embodiments, the method 600 may further include transmitting a configuration related to the uplink reference signal for power amplifier measurement. In some embodiments, the method 600 may include receiving another uplink reference signal, where the uplink reference signal may be transmitted with a determined digital pre-distortion function adjusted based on the one or more power amplifier parameters, e.g., in a manner similar to that 116 of FIG. 1. In some embodiments, the artificial intelligence-based model may include a neural network-based model. In some embodiments, the signaling may further include one or more digital pre-distortion function parameters.

As described above, FIG. 6 is provided as an example. Other examples are possible according to some embodiments.

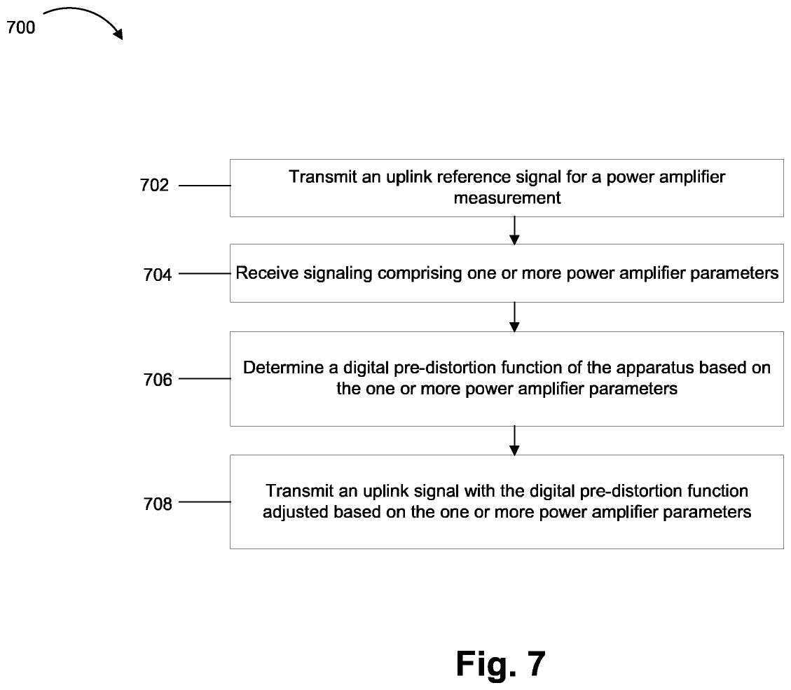

FIG. 7 illustrates an example flow diagram of a method 700, according to some embodiments. For example, FIG. 7 may illustrate example operations of a UE (e.g., apparatus 20 illustrated in, and described with respect to, FIG. 8b). Some of the operations illustrated in FIG. 7 may be similar to some operations shown in, and described with respect to, FIGS. 1-5.

In an embodiment, the method 700 may include, at 702, transmitting an uplink reference signal for power amplifier measurement, e.g., in a manner similar to that at 104 of FIG. 1 and/or at 218 and 220 of FIG. 2. The method 700 may include, at 704, receiving signaling comprising one or more power amplifier parameters, e.g., in a manner similar to that at 112 of FIG. 1 and/or that at 232 of FIG. 2. The method 700 may further include, at 706, determining a digital pre-distortion function of the apparatus based on the one or more power amplifier parameters, e.g., in a manner similar to that at 114 of FIG. 1. The method 700 may further include, at 708, transmitting an uplink signal with the digital pre-distortion function adjusted based on the one or more power amplifier parameters, e.g., in a manner similar to that at 116 of FIG. 1.

The method illustrated in FIG. 7 may include one or more additional aspects described below or elsewhere herein. In some embodiments, the determining at 706 may include using an analytical model to determine the digital pre-distortion function based on the one or more power amplifier parameters. In some embodiments, the determining at 706 may include using a trained artificial intelligence-based model to determine the digital pre-distortion function, e.g., in a manner similar to that performed by the DPD AI-based model training elements 404, 504, the PA mathematical models 406, 506, and/or the nonlinear power difference elements 408, 508 of FIGS. 4 and 5. In some embodiments, the method 700 may include training an artificial intelligence-based model to fit a power amplifier model controlled by the one or more power amplifier parameters, e.g., in a manner similar to that performed by the DPD AI-based model training element 404 of FIG. 4. The training may form the trained artificial intelligence-based model and the training may be based on an uplink reference signal transmitted to a network node (e.g., the signal at 410 of FIG. 4) and a non-linear power profile difference between the uplink reference signal and a known reference signal associated with the power amplifier model (e.g., as determined by the nonlinear power difference element 408 and provided at 420 of FIG. 4).

In some embodiments, the method 700 may include training an artificial intelligence-based model to fit a power amplifier model controlled by the one or more power amplifier parameters, e.g., in a manner similar to that performed by the DPD AI-based model training element 504 of FIG. 5. The training may form the trained artificial intelligence-based model and the training may be based on an uplink reference signal transmitted to a network node (e.g., the signal at 510 of FIG. 5), a non-linear power profile difference between the uplink reference signal and a known reference signal associated with the power amplifier model (e.g., as determined by the nonlinear power difference element 508 and provided at 520 of FIG. 5), and the one or more power amplifier parameters (e.g., provided at 524 of FIG. 5). In some embodiments, the transmitting at 708 may include transmitting the uplink signal with the digital pre-distortion function determined using the trained artificial intelligence model, e.g., in a manner similar to that at 116 of FIG. 1. In some embodiments, the one or more power amplifier parameters may include an alpha parameter or a beta parameter associated with a general analytical power amplifier model. In some embodiments, the signaling may further include one or more digital pre-distortion function parameters.

As described above, FIG. 7 is provided as an example. Other examples are possible according to some embodiments.

FIG. 8a illustrates an example of an apparatus 10 according to an embodiment. In an embodiment, apparatus 10 may be a node, host, or server in a communications network or serving such a network. For example, apparatus 10 may be a network node, satellite, base station, a Node B, an evolved Node B (eNB), 5G Node B or access point, next generation Node B (NG-NB or gNB), and/or a WLAN access point, associated with a radio access network, such as a LTE network, 5G or NR. In some example embodiments, apparatus 10 may be an eNB in LTE or gNB in 5G.

It should be understood that, in some example embodiments, apparatus 10 may be comprised of an edge cloud server as a distributed computing system where the server and the radio node may be stand-alone apparatuses communicating with each other via a radio path or via a wired connection, or they may be located in a same entity communicating via a wired connection. For instance, in certain example embodiments where apparatus 10 represents a gNB, it may be configured in a central unit (CU) and distributed unit (DU) architecture that divides the gNB functionality. In such an architecture, the CU may be a logical node that includes gNB functions such as transfer of user data, mobility control, radio access network sharing, positioning, and/or session management, etc. The CU may control the operation of DU(s) over a front-haul interface. The DU may be a logical node that includes a subset of the gNB functions, depending on the functional split option. It should be noted that one of ordinary skill in the art would understand that apparatus 10 may include components or features not shown in FIG. 8a.

As illustrated in the example of FIG. 8a, apparatus 10 may include a processor 12 for processing information and executing instructions or operations. Processor 12 may be any type of general or specific purpose processor. In fact, processor 12 may include one or more of general-purpose computers, special purpose computers, microprocessors, digital signal processors (DSPs), field-programmable gate arrays (FPGAs), application-specific integrated circuits (ASICs), and processors based on a multi-core processor architecture, as examples. While a single processor 12 is shown in FIG. 8a, multiple processors may be utilized according to other embodiments. For example, it should be understood that, in certain embodiments, apparatus 10 may include two or more processors that may form a multiprocessor system (e.g., in this case processor 12 may represent a multiprocessor) that may support multiprocessing. In certain embodiments, the multiprocessor system may be tightly coupled or loosely coupled (e.g., to form a computer cluster).

Processor 12 may perform functions associated with the operation of apparatus 10, which may include, for example, precoding of antenna gain/phase parameters, encoding and decoding of individual bits forming a communication message, formatting of information, and overall control of the apparatus 10, including processes related to management of communication or communication resources.

Apparatus 10 may further include or be coupled to a memory 14 (internal or external), which may be coupled to processor 12, for storing information and instructions that may be executed by processor 12. Memory 14 may be one or more memories and of any type suitable to the local application environment, and may be implemented using any suitable volatile or nonvolatile data storage technology such as a semiconductor-based memory device, a magnetic memory device and system, an optical memory device and system, fixed memory, and/or removable memory. For example, memory 14 can be comprised of any combination of random access memory (RAM), read only memory (ROM), static storage such as a magnetic or optical disk, hard disk drive (HDD), or any other type of non-transitory machine or computer readable media. The instructions stored in memory 14 may include program instructions or computer program code that, when executed by processor 12, enable the apparatus 10 to perform tasks as described herein.

In an embodiment, apparatus 10 may further include or be coupled to (internal or external) a drive or port that is configured to accept and read an external computer readable storage medium, such as an optical disc, USB drive, flash drive, or any other storage medium. For example, the external computer readable storage medium may store a computer program or software for execution by processor 12 and/or apparatus 10.

In some embodiments, apparatus 10 may also include or be coupled to one or more antennas 15 for transmitting and receiving signals and/or data to and from apparatus 10. Apparatus 10 may further include or be coupled to a transceiver 18 configured to transmit and receive information. The transceiver 18 may include, for example, a plurality of radio interfaces that may be coupled to the antenna(s) 15. The radio interfaces may correspond to a plurality of radio access technologies including one or more of GSM, NB-IoT, LTE, 5G, WLAN, Bluetooth, BT-LE, NFC, radio frequency identifier (RFID), ultrawideband (UWB), MulteFire, and the like. The radio interface may include components, such as filters, converters (for example, digital-to-analog converters and the like), mappers, a Fast Fourier Transform (FFT) module, and the like, to generate symbols for a transmission via one or more downlinks and to receive symbols (for example, via an uplink).

As such, transceiver 18 may be configured to modulate information on to a carrier waveform for transmission by the antenna(s) 15 and demodulate information received via the antenna(s) 15 for further processing by other elements of apparatus 10. In other embodiments, transceiver 18 may be capable of transmitting and receiving signals or data directly. Additionally or alternatively, in some embodiments, apparatus 10 may include an input and/or output device (I/O device).

In an embodiment, memory 14 may store software modules that provide functionality when executed by processor 12. The modules may include, for example, an operating system that provides operating system functionality for apparatus 10. The memory may also store one or more functional modules, such as an application or program, to provide additional functionality for apparatus 10. The components of apparatus 10 may be implemented in hardware, or as any suitable combination of hardware and software.

According to some embodiments, processor 12 and memory 14 may be included in or may form a part of processing circuitry or control circuitry. In addition, in some embodiments, transceiver 18 may be included in or may form a part of transceiver circuitry.

As used herein, the term “circuitry” may refer to hardware-only circuitry implementations (e.g., analog and/or digital circuitry), combinations of hardware circuits and software, combinations of analog and/or digital hardware circuits with software/firmware, any portions of hardware processor(s) with software (including digital signal processors) that work together to cause an apparatus (e.g., apparatus 10) to perform various functions, and/or hardware circuit(s) and/or processor(s), or portions thereof, that use software for operation but where the software may not be present when it is not needed for operation. As a further example, as used herein, the term “circuitry” may also cover an implementation of merely a hardware circuit or processor (or multiple processors), or portion of a hardware circuit or processor, and its accompanying software and/or firmware. The term circuitry may also cover, for example, a baseband integrated circuit in a server, cellular network node or device, or other computing or network device.

As introduced above, in certain embodiments, apparatus 10 may be a network node or RAN node, such as a base station, access point, Node B, eNB, gNB, WLAN access point, or the like.

According to certain embodiments, apparatus 10 may be controlled by memory 14 and processor 12 to perform the functions associated with any of the embodiments described herein, such as some operations illustrated in, or described with respect to, FIGS. 1-6. For instance, apparatus 10 may be controlled by memory 14 and processor 12 to perform the method of FIG. 6.

FIG. 8b illustrates an example of an apparatus 20 according to another embodiment. In an embodiment, apparatus 20 may be a node or element in a communications network or associated with such a network, such as a UE, mobile equipment (ME), mobile station, mobile device, stationary device, IoT device, or other device. As described herein, a UE may alternatively be referred to as, for example, a mobile station, mobile equipment, mobile unit, mobile device, user device, subscriber station, wireless terminal, tablet, smart phone, IoT device, sensor or NB-IoT device, a watch or other wearable, a head-mounted display (HMD), a vehicle, a drone, a medical device and applications thereof (e.g., remote surgery), an industrial device and applications thereof (e.g., a robot and/or other wireless devices operating in an industrial and/or an automated processing chain context), a consumer electronics device, a device operating on commercial and/or industrial wireless networks, or the like. As one example, apparatus 20 may be implemented in, for instance, a wireless handheld device, a wireless plug-in accessory, or the like.

In some example embodiments, apparatus 20 may include one or more processors, one or more computer-readable storage medium (for example, memory, storage, or the like), one or more radio access components (for example, a modem, a transceiver, or the like), and/or a user interface. In some embodiments, apparatus 20 may be configured to operate using one or more radio access technologies, such as GSM, LTE, LTE-A, NR, 5G, WLAN, WiFi, NB-IoT, Bluetooth, NFC, MulteFire, and/or any other radio access technologies. It should be noted that one of ordinary skill in the art would understand that apparatus 20 may include components or features not shown in FIG. 8b.

As illustrated in the example of FIG. 8b, apparatus 20 may include or be coupled to a processor 22 for processing information and executing instructions or operations. Processor 22 may be any type of general or specific purpose processor. In fact, processor 22 may include one or more of general-purpose computers, special purpose computers, microprocessors, digital signal processors (DSPs), field-programmable gate arrays (FPGAs), application-specific integrated circuits (ASICs), and processors based on a multi-core processor architecture, as examples. While a single processor 22 is shown in FIG. 8b, multiple processors may be utilized according to other embodiments. For example, it should be understood that, in certain embodiments, apparatus 20 may include two or more processors that may form a multiprocessor system (e.g., in this case processor 22 may represent a multiprocessor) that may support multiprocessing. In certain embodiments, the multiprocessor system may be tightly coupled or loosely coupled (e.g., to form a computer cluster).

Processor 22 may perform functions associated with the operation of apparatus 20 including, as some examples, precoding of antenna gain/phase parameters, encoding and decoding of individual bits forming a communication message, formatting of information, and overall control of the apparatus 20, including processes related to management of communication resources.

Apparatus 20 may further include or be coupled to a memory 24 (internal or external), which may be coupled to processor 22, for storing information and instructions that may be executed by processor 22. Memory 24 may be one or more memories and of any type suitable to the local application environment, and may be implemented using any suitable volatile or nonvolatile data storage technology such as a semiconductor-based memory device, a magnetic memory device and system, an optical memory device and system, fixed memory, and/or removable memory. For example, memory 24 can be comprised of any combination of random access memory (RAM), read only memory (ROM), static storage such as a magnetic or optical disk, hard disk drive (HDD), or any other type of non-transitory machine or computer readable media. The instructions stored in memory 24 may include program instructions or computer program code that, when executed by processor 22, enable the apparatus 20 to perform tasks as described herein.

In an embodiment, apparatus 20 may further include or be coupled to (internal or external) a drive or port that is configured to accept and read an external computer readable storage medium, such as an optical disc, USB drive, flash drive, or any other storage medium. For example, the external computer readable storage medium may store a computer program or software for execution by processor 22 and/or apparatus 20.

In some embodiments, apparatus 20 may also include or be coupled to one or more antennas 25 for receiving a downlink signal and for transmitting via an uplink from apparatus 20. Apparatus 20 may further include a transceiver 28 configured to transmit and receive information. The transceiver 28 may also include a radio interface (e.g., a modem) coupled to the antenna 25. The radio interface may correspond to a plurality of radio access technologies including one or more of GSM, LTE, LTE-A, 5G, NR, WLAN, NB-IoT, Bluetooth, BT-LE, NFC, RFID, UWB, and the like. The radio interface may include other components, such as filters, converters (for example, digital-to-analog converters and the like), symbol demappers, signal shaping components, an Inverse Fast Fourier Transform (IFFT) module, and the like, to process symbols, such as OFDMA symbols, carried by a downlink or an uplink.

For instance, transceiver 28 may be configured to modulate information on to a carrier waveform for transmission by the antenna(s) 25 and demodulate information received via the antenna(s) 25 for further processing by other elements of apparatus 20. In other embodiments, transceiver 28 may be capable of transmitting and receiving signals or data directly. Additionally or alternatively, in some embodiments, apparatus 20 may include an input and/or output device (I/O device). In certain embodiments, apparatus 20 may further include a user interface, such as a graphical user interface or touchscreen.

In an embodiment, memory 24 stores software modules that provide functionality when executed by processor 22. The modules may include, for example, an operating system that provides operating system functionality for apparatus 20. The memory may also store one or more functional modules, such as an application or program, to provide additional functionality for apparatus 20. The components of apparatus 20 may be implemented in hardware, or as any suitable combination of hardware and software. According to an example embodiment, apparatus 20 may optionally be configured to communicate with apparatus 10 via a wireless or wired communications link 70 according to any radio access technology, such as NR.

According to some embodiments, processor 22 and memory 24 may be included in or may form a part of processing circuitry or control circuitry. In addition, in some embodiments, transceiver 28 may be included in or may form a part of transceiving circuitry. As discussed above, according to some embodiments, apparatus 20 may be a UE, mobile device, mobile station, ME, IoT device and/or NB-IoT device, for example. According to certain embodiments, apparatus 20 may be controlled by memory 24 and processor 22 to perform the functions associated with any of the embodiments described herein, such as some operations illustrated in, or described with respect to, FIGS. 1-5 and 7. For instance, in one embodiment, apparatus 20 may be controlled by memory 24 and processor 22 to perform the method of FIG. 7.

In some embodiments, an apparatus (e.g., apparatus 10 and/or apparatus 20) may include means for performing a method or any of the variants discussed herein, e.g., a method described with reference to FIG. 6 or 7. Examples of the means may include one or more processors, memory, and/or computer program code for causing the performance of the operation.

Therefore, certain example embodiments provide several technological improvements, enhancements, and/or advantages over existing technological processes. For example, one benefit of some example embodiments is improved UE PA linearity and PA efficiency. Accordingly, the use of some example embodiments results in improved functioning of communications networks and their nodes and, therefore constitute an improvement at least to the technological field of DPD function determination, among others.

In some example embodiments, the functionality of any of the methods, processes, signaling diagrams, algorithms or flow charts described herein may be implemented by software and/or computer program code or portions of code stored in memory or other computer readable or tangible media, and executed by a processor.

In some example embodiments, an apparatus may be included or be associated with at least one software application, module, unit or entity configured as arithmetic operation(s), or as a program or portions of it (including an added or updated software routine), executed by at least one operation processor. Programs, also called program products or computer programs, including software routines, applets and macros, may be stored in any apparatus-readable data storage medium and may include program instructions to perform particular tasks.

A computer program product may include one or more computer-executable components which, when the program is run, are configured to carry out some example embodiments. The one or more computer-executable components may be at least one software code or portions of code. Modifications and configurations used for implementing functionality of an example embodiment may be performed as routine(s), which may be implemented as added or updated software routine(s). In one example, software routine(s) may be downloaded into the apparatus.

As an example, software or a computer program code or portions of code may be in a source code form, object code form, or in some intermediate form, and it may be stored in some sort of carrier, distribution medium, or computer readable medium, which may be any entity or device capable of carrying the program. Such carriers may include a record medium, computer memory, read-only memory, photoelectrical and/or electrical carrier signal, telecommunications signal, and/or software distribution package, for example. Depending on the processing power needed, the computer program may be executed in a single electronic digital computer or it may be distributed amongst a number of computers. The computer readable medium or computer readable storage medium may be a non-transitory medium.

In other example embodiments, the functionality may be performed by hardware or circuitry included in an apparatus (e.g., apparatus 10 or apparatus 20), for example through the use of an application specific integrated circuit (ASIC), a programmable gate array (PGA), a field programmable gate array (FPGA), or any other combination of hardware and software. In yet another example embodiment, the functionality may be implemented as a signal, such as a non-tangible means that can be carried by an electromagnetic signal downloaded from the Internet or other network.

According to an example embodiment, an apparatus, such as a node, device, or a corresponding component, may be configured as circuitry, a computer or a microprocessor, such as single-chip computer element, or as a chipset, which may include at least a memory for providing storage capacity used for arithmetic operation(s) and/or an operation processor for executing the arithmetic operation(s).

Example embodiments described herein apply equally to both singular and plural implementations, regardless of whether singular or plural wording is used in connection with describing certain embodiments. For example, an embodiment that describes operations of a single network node equally applies to embodiments that include multiple instances of the network node, and vice versa.

One having ordinary skill in the art will readily understand that the example embodiments as discussed above may be practiced with operations in a different order, and/or with hardware elements in configurations which are different than those which are disclosed. Therefore, although some embodiments have been described based upon these example embodiments, it would be apparent to those of skill in the art that certain modifications, variations, and alternative constructions would be apparent, while remaining within the spirit and scope of example embodiments.

### PARTIAL GLOSSARY

5G NR 5G New Radio
DPD Digital Pre-Distortion
gNB 5G Base Station
LOS Line-of-Sight
MAC CE MAC Control Element
NN Neural Network
OFDM Orthogonal Frequency Division Multiplexing
PA Power Amplifier
PAPR Peak-To-Average Power Ratio
PDCCH Physical Downlink Control Channel
PMRS Power Measurement Reference Signal
RS Reference Signal
Tx Transmitter
UE User Equipment

1. An apparatus, comprising:
at least one processor; and
at least one memory including computer program code,
wherein the at least one memory and the computer program code are configured to, with the at least one processor, cause the apparatus at least to:
receive an uplink reference signal for power amplifier measurement;
measure a power amplifier nonlinearity of a user equipment based on the uplink reference signal;
train an artificial intelligence-based model to approximate one or more power amplifier parameters based on an estimation of the power amplifier nonlinearity;
use the trained artificial intelligence-based model to approximate the one or more power amplifier parameters; and
transmit, to a user equipment, signaling comprising the one or more power amplifier parameters.

2. The apparatus according to claim 1, wherein the at least one memory and the computer program code are configured to, with the at least one processor, further cause the apparatus, when measuring the power amplifier nonlinearity, at least to:
determine a power amplifier power profile difference between the received uplink reference signal and an output power profile associated with a known reference signal.

3. The apparatus according to claim 2, wherein the at least one memory and the computer program code are configured to, with the at least one processor, further cause the apparatus, when training the artificial intelligence-based model, at least to:
train the artificial intelligence-based model using the power profile difference and a training criterion comprising minimization of the power difference.

4. The apparatus according to claim 2, wherein the known reference signal is generated based on an analytical power amplifier model.

5. The apparatus according to claim 1, wherein the one or more power amplifier parameters comprise an alpha parameter or a beta parameter associated with a general analytical power amplifier model.

6. The apparatus according to claim 1, wherein the at least one memory and the computer program code are configured to, with the at least one processor, further cause the apparatus at least to:
transmit a configuration related to the uplink reference signal for power amplifier measurement.

7. The apparatus according to claim 1, wherein the at least one memory and the computer program code are configured to, with the at least one processor, further cause the apparatus at least to:
receive another uplink reference signal, wherein the uplink reference signal is transmitted with a determined digital pre-distortion function adjusted based on the one or more power amplifier parameters.

8. The apparatus according to claim 1, wherein the artificial intelligence-based model comprises a neural network-based model.

9. The apparatus according to claim 1, wherein the transmitted signaling further comprises one or more digital pre-distortion function parameters.

10. An apparatus, comprising:
at least one processor; and
at least one memory including computer program code,
wherein the at least one memory and the computer program code are configured to, with the at least one processor, cause the apparatus at least to:
transmit an uplink reference signal for power amplifier measurement;
receive signaling comprising one or more power amplifier parameters;
determine a digital pre-distortion function of the apparatus based on the one or more power amplifier parameters; and
transmit an uplink signal with the digital pre-distortion function adjusted based on the one or more power amplifier parameters.

11. The apparatus according to claim 10, wherein the at least one memory and the computer program code are configured to, with the at least one processor, further cause the apparatus, when determining the digital pre-distortion function, at least to:
use an analytical model to determine the digital pre-distortion function based on the one or more power amplifier parameters.

12. The apparatus according to claim 10, wherein the at least one memory and the computer program code are configured to, with the at least one processor, further cause the apparatus, when determining the digital pre-distortion function, at least to:
use a trained artificial intelligence-based model to determine the digital pre-distribution function.

13. The apparatus according to claim 12, wherein the at least one memory and the computer program code are configured to, with the at least one processor, further cause the apparatus at least to:
train an artificial intelligence-based model to fit a power amplifier model controlled by the one or more power amplifier parameters, wherein the training forms the trained artificial intelligence-based model, wherein the training is based on an uplink reference signal transmitted to a network node and a non-linear power profile difference between the uplink reference signal and a known reference signal associated with the power amplifier model.

14. The apparatus according to claim 12, wherein the at least one memory and the computer program code are configured to, with the at least one processor, further cause the apparatus at least to:
train an artificial intelligence-based model to fit a power amplifier model controlled by the one or more power amplifier parameters, wherein the training forms the trained artificial intelligence-based model, wherein the training is based on an uplink reference signal transmitted to a network node, a non-linear power profile difference between the uplink reference signal and a known reference signal associated with the power amplifier model, and the one or more power amplifier parameters.

15. The apparatus according to claim 12, wherein the at least one memory and the computer program code are configured to, with the at least one processor, further cause the apparatus, when transmitting the uplink signal, at least to:
transmit the uplink signal with the digital pre-distortion function determined using the trained artificial intelligence model.

16. The apparatus according to claim 10, wherein the one or more power amplifier parameters comprise an alpha parameter or a beta parameter associated with a general analytical power amplifier model.

17. The apparatus according to claim 10, wherein the received signaling further comprises one or more digital pre-distortion function parameters.

18. A method, comprising:
receiving an uplink reference signal for power amplifier measurement;
measuring a power amplifier nonlinearity of a user equipment based on the uplink reference signal;
training an artificial intelligence-based model to approximate one or more power amplifier parameters based on an estimation of the power amplifier nonlinearity;
using the trained artificial intelligence-based model to approximate the one or more power amplifier parameters; and
transmitting, to a user equipment, signaling comprising the one or more power amplifier parameters.

19-26. (canceled)

27. A method, comprising:
transmitting, by a user equipment, an uplink reference signal for power amplifier measurement;
receiving signaling comprising one or more power amplifier parameters;
determining a digital pre-distortion function of the user equipment based on the one or more power amplifier parameters; and
transmitting an uplink signal with the digital pre-distortion function adjusted based on the one or more power amplifier parameters.

28. The method according to claim 27, wherein the determining the digital pre-distortion function further comprises:
using an analytical model to determine the digital pre-distortion function based on the one or more power amplifier parameters.

29-37. (canceled)
